(19) United States
(12) Patent Application Publication
(10) Pub. No.: US 2023/0343745 A1
(43) Pub. Date: Oct. 26, 2023

(54) METHOD FOR CONTACTING A POWER SEMICONDUCTOR ON A SUBSTRATE

(71) Applicant: Siemens Aktiengesellschaft, München (DE)

(72) Inventors: Claus Florian Wagner, Nürnberg (DE); MICHAEL WOITON, Nürnberg (DE)

(73) Assignee: Siemens Aktiengesellschaft, München (DE)

(21) Appl. No.: 18/012,554

(22) PCT Filed: Apr. 30, 2021
(86) PCT No.: PCT/EP2021/061372

§ 371 Date: Dec. 22, 2022

(30) Foreign Application Priority Data
Jun. 23, 2020 (EP) 20181634.5

(51) Int. Cl. H01L 23/00

(52) U.S. Cl. CPC H01L 24/83; H01L 24/73; H01L 2224/8384; H01L 2224/73253; H01L 2924/30107; H01L 2924/13055; H01L 2224/83203

(57) ABSTRACT

A method for contacting a power semiconductor device on a substrate is disclosed. In order to achieve improved switching behavior and a higher maximum current density, the power semiconductor device has, on a side facing the substrate, at least two contact regions which are electrically isolated from one another, and which are connected by a material bond to the substrate by a structured, in particular metal, connecting layer which includes at least two sintered layers.

The invention relates to a method for contacting a power semiconductor on a substrate.

Furthermore, the invention relates to a power semiconductor module with a power semiconductor and a substrate.

Furthermore, the invention relates to a converter with at least one power semiconductor module of this type.

Semiconductor devices, for instance switching elements, generally in the form of power modules or in the form of discrete packages, are disposed in power converters of this type. A power converter is understood to be, for example, a rectifier, an inverter, a converter or a DC-DC converter. Switching elements of this type are for instance transistors, in particular embodied as insulated gate bipolar transistors (IGBTs), metal oxide semiconductor field effect transistors (MOSFETs) or as field effect transistors. The semiconductor devices are typically contacted by means of specific wire bonding technologies and the power modules are fastened to a circuit carrier by means of soldered, spring-release or crimped connections, for instance. The maximum permissible current density is limited by the use of bonding wires. Moreover, bonding wires generate parasitic inductances which limit a maximum achievable switching speed of the switching elements.

The unexamined patent application EP 3 105 784 A1 describes a method for mounting an electrical component on a substrate. The joining is simplified by a hood, by a contacting structure being provided in this hood and when the hood is placed on different joining levels this is joined simultaneously with a filler material.

The unexamined patent application DE 2020 12 004 434 U1 describes a metal mold for creating a connection between a power semiconductor with potential surfaces on the top side and thick wires or bands, characterized by a metal mold (6a, 6b), which overhangs one or more potential surfaces and from which at least one segment (6b) is separated in an electrically isolated manner from the remaining metal mold, said segment extending from a contacting section on a potential surface of the power semiconductor to a fastening section for thick wires which is at a lateral distance therefrom.

The unexamined patent application DE 10 2014 222 819 A1 describes a method for forming a power semiconductor contact structure in a power semiconductor module, which has a substrate and a metal mold. The power semiconductor contact structure is firstly embodied by applying a layer of sintered material with a locally varying thickness to either the metal mold or the substrate, and then sintering together the contacting film with the substrate by way of the connection-supporting properties of the sintered material layer, wherein the contacting film achieves its shape in a distinct manner in accordance with the varying thickness of the layer of sintered material.

The unexamined patent application US 2018/0374813 A1 describes an arrangement having at least a first element, which comprises at least a first electrical contacting field; at least a second element, which comprises at least a second electrical contacting field; electrical and mechanical connecting means, wherein the electrical and mechanical connecting means comprise at least the following: at least one first metal intermediary connecting element on the surface of at least the first electrical contact spot; at least a sintered connection comprising metal microparticles or nanoparticles, which is stacked with the first metal intermediary connecting element; wherein the melting point of the first metal intermediary connecting element is greater than the sintering temperature of the metal microparticies or nanoparticles.

The publication Cao X et al: “Height Optimization for a Medium-Voltage Planar Package” describes a method for optimizing the connection height in a power module, which is based on the compromise between thermomechanical power and dielectric power of the power module.

The publication Jiang L et al: “Evaluation of Thermal Cycling Reliability of Sintered Nanosilver Versus Soldered Joints by Curvature Measurement” describes a low temperature silver sintering technology, which is applied as a lead-free chip fastening saltation which significantly improves the heat dissipation and reliability of power devices and modules, which are connected to solder alloys.

The unexamined patent application EP 0 242 626 A2 describes a method for fastening electronic components to a substrate by means of pressure sintering.

Against this background, an object of the present invention is to specify a method for contacting a power semiconductor on a substrate, by means of which an improved switching behavior and a higher maximum current density is achieved.

The object is achieved according to the invention by a method for contacting a power semiconductor on a substrate, wherein on a side facing the substrate the power semiconductor has at least two contact areas which are electrically isolated from one another, wherein the at least two contact areas of the power semiconductor which are electrically isolated from one another are connected with a material bond to the substrate by means of a structured, metal connecting layer which comprises at least two substantially closed sintered layers, wherein the substantially closed sintered layers are applied by way of a template, wherein a first sintered layer is applied to the substrate and is at least partially dried, wherein at least one second sintered layer is applied to the first sintered layer and is at least partially dried, wherein the at least two contact areas of the power semiconductor which are electrically isolated from one another are contacted on the second sintered layer, in particular by means of pressing and are thereupon connected with a material bond to the substrate by sintering the at least two sintered layers, wherein the first sintered layer is applied by means of a first template, wherein the second sintered layer is applied by means of a second template and wherein the second template is thicker than the first template.

Moreover, the object is achieved according to the invention by a method for producing a power semiconductor module with a power semiconductor and a substrate, wherein on a side facing the substrate the power semiconductor has at least two contact areas which are electrically isolated from one another, wherein the at least two contact areas of the power semiconductor which are electrically isolated from one another are connected with a material bond to the substrate by means of a structured metal connecting layer, which comprises at least two substantially closed sintered layers, wherein the substantially closed sintered layers are applied by way of a template, wherein a first sintered layer is applied to the substrate and is at least partially dried, wherein at least one second sintered layer is applied to a transfer unit and is at least partially dried, wherein the at least partially dried second sintered layer is transferred by the transfer unit to the first sintered layer, wherein the at least two contact areas of the power semiconductor which are electrically isolated from one other are contacted on the second sintered layer, in particular by means of pressing and are thereupon connected with a material bond to the substrate by sintering the at least two sintered layers.

Moreover, the object is achieved according to the invention by a method for producing a power semiconductor module with a power semiconductor and a substrate, wherein on a side facing the substrate the power semiconductor has at least two contact areas which are electrically isolated from one another, wherein the at least two contact areas of the power semiconductor which are electrically isolated from one another are connected with a material bond to the substrate (4) by means of a structured metal connecting layer, which comprises at least two substantially closed sintered layers, wherein the substantially closed sintered layers are applied by way of a template, wherein a first sintered layer is applied to the substrate and is at least partially dried, wherein at least one second sintered layer is applied to a metal mold and is at least partially dried, wherein the metal mold with a side facing away from the at least partially dried second sintered layer is positioned on the first sintered layer, wherein the at least two contact areas of the power semiconductor which are electrically isolated from one another are contacted on the second sintered layer, in particular by means of pressing and are thereupon connected with a material bond to the substrate by sintering the at least two sintered layers.

Moreover, the object is achieved according to the invention by a method for producing a power semiconductor module with a power semiconductor and a substrate, wherein on a side facing the substrate the power semiconductor has at least two contact areas which are electrically isolated from one another, wherein the at least two contact areas of the power semiconductor which are electrically isolated from one another are connected with a material bond to the substrate by means of a structured metal connecting layer, which comprises at least two substantially closed sintered layers, wherein the substantially closed sintered layers are applied by way of a template, wherein a first sintered layer is applied to the substrate and is at least partially dried, wherein a metal mold coated with a second sintered layer is provided, wherein the metal mold with a side facing away from the second sintered layer is positioned on the first sintered layer, wherein the at least two contact areas of the power semiconductor which are electrically isolated from one another are contacted on the second sintered layer, in particular by means of pressing, and are thereupon connected with a material bond to the substrate by sintering the at least two sintered layers.

Furthermore, the object is achieved according to the invention by a power semiconductor module with a power semiconductor and a substrate, wherein on the side facing the substrate the power semiconductor has at least two contact areas which are electrically isolated from one another, wherein the at least two contact areas of the power semiconductor which are electrically isolated from one another are connected with a material bond to the substrate by means of a structured metal connecting layer, which comprises at least two substantially closed sintered layers, wherein the substantially closed sintered layers are applied by way of a template, wherein at least one second sintered layer is applied to a metal mold, wherein the metal mold with a side facing away from the second sintered layer is positioned on the first sintered layer, wherein the at least two contact areas of the power semiconductor which are electrically isolated from one another are contacted on the second sintered layer, in particular by means of pressing, and are thereupon connected with a material bond to the substrate by sintering the at least two sintered layers.

Moreover, the object is achieved according to the invention by a power converter with at least one power semiconductor module.

The advantages and preferred embodiments cited below in relation to the method can be transferred analogously to the power semiconductor module and the power converter.

The idea underlying the invention is to apply a power semiconductor, which, on a side facing a substrate, has at least two contact areas which are electrically isolated from one another, by means of sintering to a substrate in order to achieve an improved switching behavior and a higher maximum current density. Examples of power semiconductors of this type are triacs, transistors or thyristors. Transistors are embodied for instance as insulated gate bipolar transistors (IGBTs), metal oxide semiconductor field effect transistors (MOSFETs) or as field effect transistors. A substrate is understood to mean a dielectric material which, at least on a side facing the power semiconductor, has an at least partially structured metallization for contacting the power semiconductor. For instance, the substrate is embodied as a DCB ceramic substrate, which contains in particular aluminum oxide and/or aluminum nitride and has a copper metallization. In particular, the power semiconductor is applied to the substrate in a flip chip arrangement. The at least two contact areas of the power semiconductor which are electrically isolated from one another are connected with a material bond to the substrate by means of a structured, in particular metal, connecting layer, wherein the connecting layer comprises at least two substantially closed sintered layers. A substantially closed sintered layer is understood to mean a layer which, in contrast to screen printing, is applied with a template without a supporting screen, so that no functionally definable cavities are present in the connecting layer. A high conductivity and a high current carrying capacity of the connecting layer are achieved by means of a substantially closed sintered layer. In order to avoid doggy ears, for instance, and to achieve a stable layer thickness, at least two substantially closed sintered layers are arranged one above the other in a direction which is orthogonal to a substrate surface. This prevents a tilted position of the chip and thus potential damage during sintering.

A further embodiment provides that the power semiconductor is contacted by the connecting layer at a distance from the substrate of at least 70 μm, in particular at least 200 μm. On account of a distance of this type, electromagnetic fields developing on the power semiconductor, which develop for instance in the region of a guard ring, do not noticeably interact with the substrate, so that the switching behavior of the power semiconductor and an isolation in the border area is not noticeably influenced by too close a proximity to the substrate; this results in an increase in the service life.

A further embodiment provides that the at least two substantially closed sintered layers are produced from a suspension which contains in particular metal solid state particles and a binding means, By way of example, silver sinter paste is used. A high conductivity and a high current carrying capacity of the connecting layer are achieved by means of a suspension of this type.

A further embodiment provides that a first sintered layer is applied to the substrate and is at least partially dried, wherein at least one second sintered layer is applied to the first sintered layer and is at least partially dried, wherein the at least two contact areas of the power semiconductor which are electrically isolated from one another are contacted on the second sintered layer, in particular by means of pressing, and are thereupon connected with a material bond to the substrate by means of sintering the at least two sintered layers. By means of drying, which takes place for instance at a temperature of between 100° C. and 150° C., in particular between 115° C. and 125° C., a binding means is at least partially removed, for instance. In particular, the sintering temperature, for instance when silver sintering paste is used, is between 220° C. and 260° C., in particular between 235° C. and 245° C. Sintering at least two layers, in particular compared with a thicker layer, achieves an improved structuring, in particular in a direction which is orthogonal to the substrate surface, is achieved. By avoiding bulges which develop with thick layers, an improved wall steepness of the connecting layer is achieved when several thin layers are printed. A multilayer printing method of this type is therefore avoided, so that the at least two contact areas which are electrically isolated from one another do not electrically and/or magnetically influence one another or are even short-circuited in the case of a layer thickness of for instance at least 70 μm.

A further embodiment provides that the first sintered layer is applied by means of a first template, wherein the second sintered layer is applied by means of a second template, and wherein the second template is thicker than the first template. In particular, the second template is substantially twice as thick as the first template. For instance, the templates are embodied so that while the respective sintered layer is being applied, these rest in particular in a planar manner on the substrate. The use of templates of this type prevents the first sintered layer from deforming when the second sintered layer is applied.

A further embodiment provides that a first sintered layer is applied to the substrate and is at least partially dried, wherein at least one second sintered layer is applied to a transfer unit and is at least partially dried, wherein the at least partially dried second sintered layer is transferred by the transfer unit to the first sintered layer, wherein the at least two contact areas of the power semiconductor which are electrically isolated from one another are contacted on the second sintered layer, in particular by means of pressing and are thereupon connected with a material bond to the substrate by sintering the at least two sintered layers. By way of example, the first sintered layer is applied to the substrate by means of a first template, wherein the second sintered layer is applied with the first template arranged inverted. The transfer unit is embodied for instance as a Teflon-coated sheet metal, in particular aluminum sheet, in order to enable a simple transfer of the at least one second sintered layer. For instance, the transfer takes place by means of printing and a particularly low increase in temperature, wherein the temperature for transferring the at least one second sintered layer lies clearly below the sintering temperature. By using a transfer unit, any number of sintered layers can be applied without additional templates, which saves on costs during manufacture.

A further embodiment provides that the first sintered layer is applied to the substrate by means of a first template, wherein the second sintered layer is applied to the transfer unit by means of a template which is mirror-symmetrical with respect to the first template. The application by means of the mirror-symmetrical template is carried out in particular in parallel in terms of time, which results in a time saving. With the aid of the mirror-symmetrical template, any number of sintered layers can be produced on transfer units.

A further embodiment provides that a first sintered layer is applied to the substrate and is at least partially dried, wherein at least one second sintered layer is applied to a metal mold and is at least partially dried, wherein the metal mold with a side facing away from the at least partially dried second sintered layer is positioned on the first sintered layer, wherein the at least two contact areas of the power semiconductor which are electrically isolated from one another are contacted on the second sintered layer, in particular by means of pressing and are thereupon connected with a material bond to the substrate by sintering the at least two sintered layers.

The metal mold is produced for instance from an electrically and thermally conductive material such as copper, silver, gold, aluminum, cobalt, platinum, molybdenum and/or their alloys. By means of the metal mold, an improved wall steepness of the connecting layer is achieved and the sintering, in particular for large layer thicknesses, is simplified for instance by at least 70 μm.

A further embodiment provides that the metal mold comprises at least two metal plates, wherein the at least one second sintered layer is applied to the at least two metal plates of the metal mold by means of at least one first template. The metal plates are produced for instance from an electrically and thermally conductive material such as copper, silver, gold, aluminum, cobalt, platinum and/or their alloys. By means of the metal plates, an improved wall steepness of the connecting layer is achieved and the sintering, in particular for large layer thicknesses, is simplified for instance by at least 70 μm.

A further embodiment provides that a first sintered layer is applied to the substrate and is at least partially dried, wherein a metal mold is provided with a second sintered layer, wherein the metal mold with a side facing away from the second sintered layer is positioned on the first sintered layer, wherein the at least two contact areas of the power semiconductor which are electrically isolated from one another are contacted on the second sintered layer, in particular by means of pressing, and are thereupon connected with a material bond to the substrate sintering the at least two sintered layers. The provision of a metal mold with a sintered layer results in a time saving.

The invention is described and explained in more detail below on the basis of the exemplary embodiments shown in the Figures.

In the drawings:

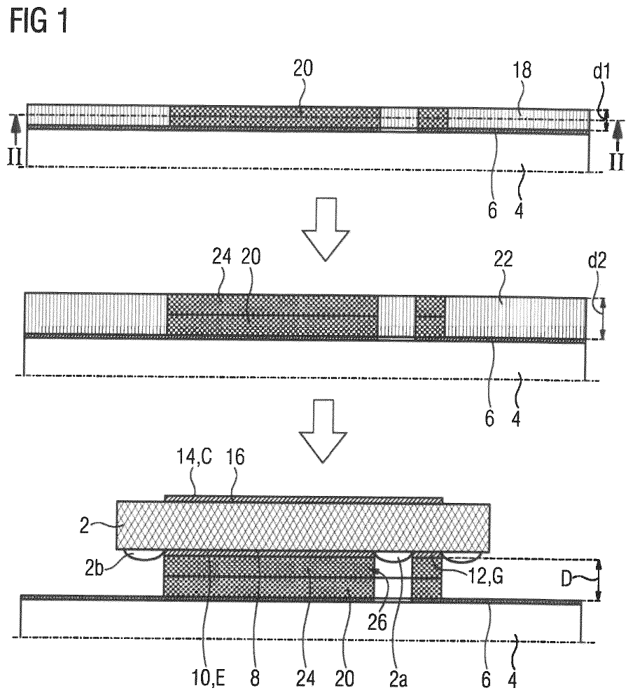

FIG. 1 shows a schematic representation of a first embodiment of a method for contacting a power semiconductor on a substrate,

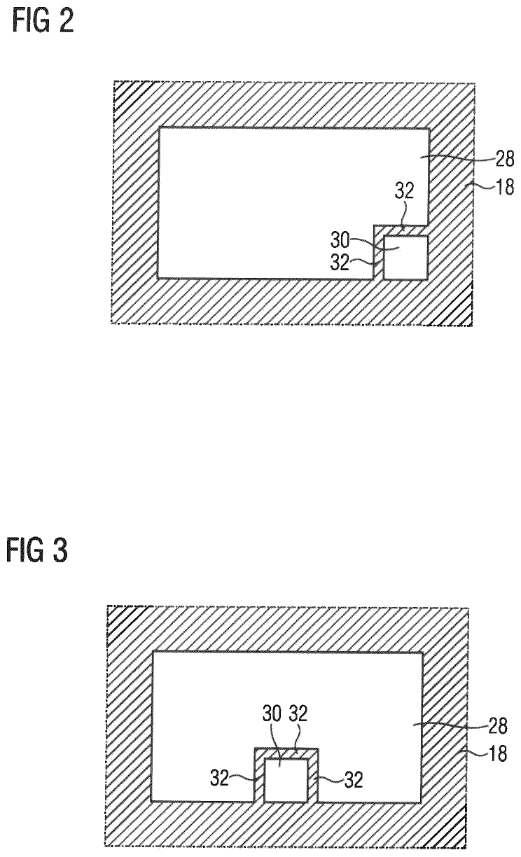

FIG. 2 shows a schematic sectional representation of a first embodiment of a template,

FIG. 3 shows a schematic sectional representation of a second embodiment of a template,

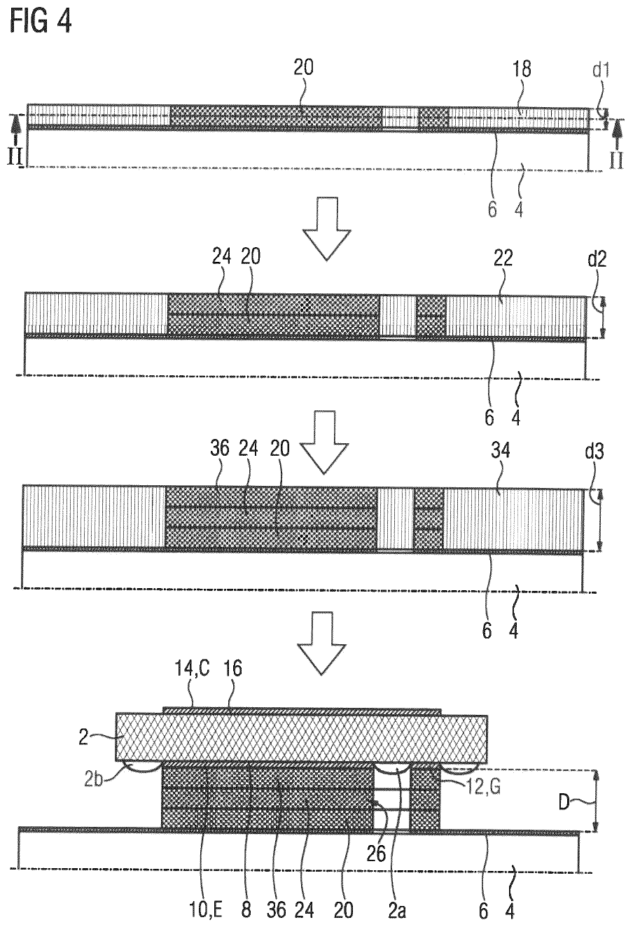

FIG. 4 shows a schematic representation of a second embodiment of a method for contacting a power semiconductor on a substrate,

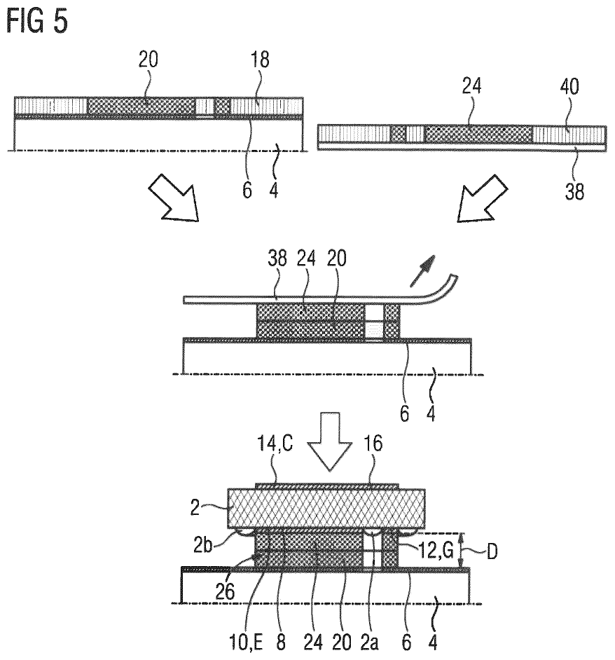

FIG. 5 shows a schematic representation of a third embodiment of a method for contacting a power semiconductor on a substrate,

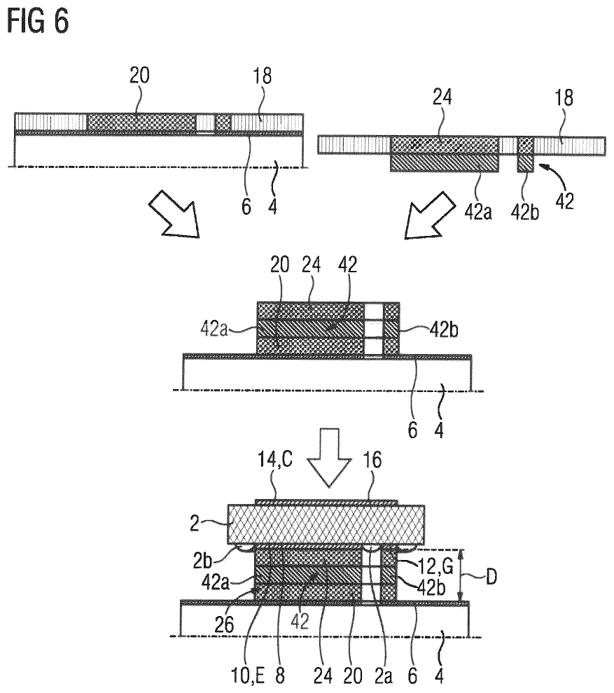

FIG. 6 shows a schematic representation of a fourth embodiment of a method for contacting a power semiconductor on a substrate and

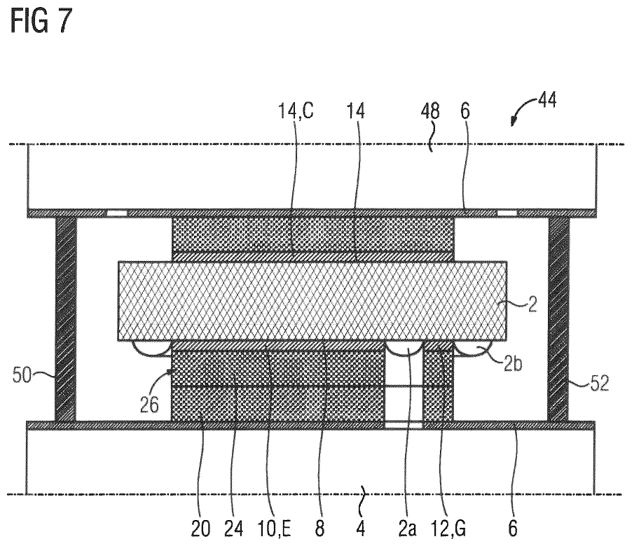

FIG. 7 shows a schematic representation of a power semiconductor module.

The exemplary embodiments set out in the following involve preferred embodiments of the invention. The components of the embodiments as described in the exemplary embodiments each represent individual features of the invention that are to be regarded as independent of one another and each also develop the invention independently of one another and are thus also to be considered individually, or in a different combination from that shown, as a constituent part of the invention. Furthermore, the embodiments described can also be enhanced by others of the previously described features of the invention.

The same reference signs have the same meaning in the different figures.

FIG. 1 shows a schematic representation of a first embodiment of a method for contacting a power semiconductor 2 on a substrate 4. The substrate is embodied as a DCB ceramic substrate, which contains aluminum oxide and/or aluminum nitride for instance and has an at least partially structured metallization 6, in particular copper metallization. The power semiconductor 2 is embodied by way of example as an IGBT (Insulated Gate Bipolar Transistor) and is applied to the substrate 4 in a flip chip arrangement. Accordingly on a side 8 facing the substrate 4, the IGBT has two contact areas 10, 12 which are electrically isolated from one another, wherein the first contact area 10 is embodied as an emitter contact E and the second contact area 12 as a gate contact G. The contact areas are embodied in particular as pads and have a metallization. A third contact area 14, which is embodied as a collector contact C, is located on a side 10 facing away from the substrate 4. Furthermore, the power semiconductor 2 has an electrically isolated intermediate area 2a between the contact areas 10, 12. Moreover, the power semiconductor 2 has a guard ring 2b, which comprises a glass or polyamide cover with a thickness of 10-15 μm for instance. The power semiconductor 2 can also be embodied as a field effect transistor or bipolar transistor, for instance.

Firstly, a closed first sintered layer 20 is applied to the substrate 4 by means of a first template 18 and after removing the first template 18 is at least partially dried. The first template 18 has for instance a first thickness d1 of 80-100 μm and when the first sintered layer 20 is being applied rests in particular in a planar manner on the substrate 4. The first sintered layer 20 is produced for instance from a suspension, which contains metal solid state particles and an in particular organic binding means. For instance, silver sinter paste is used for the first sintered layer. By means of drying at a temperature of between 100° C. and 150° C., in particular between 115° C. and 125° C., the binding means is at least partially removed.

A closed second sintered layer 24 is thereupon applied to the first sintered layer 20 by means of a second template 22 and after removing the second template 22 is at least partially dried. The second sintered layer 24 is produced from the same material as the first sintered layer 20 and is dried analogously to the first sintered layer 20. The second template 22 has for instance a second thickness d2 of 120-200 μm. In particular, when the second sintered layer 24 is being applied the second template 22 rests in particular in a planar manner on the substrate 4.

In a further step, the two contact areas 10, 12 of the power semiconductor 2 which are electrically isolated from one another are contacted on the second sintered layer 24, in particular by means of pressing. The power semiconductor 2 is thereupon connected with a material bond to the substrate 4 by means of sintering the sintered layers 20, 24. When silver sinter paste is used for instance, the sintering temperature lies between 220° C. and 260° C., in particular between 235° C. and 245° C. Both during drying and also sintering, the dimensions of the sintered layers 20, 24 reduce as a function of the material used. This effect is not shown in the schematic representation in FIG. 1. By means of the sintering, a connecting layer 26 is produced, by means of which the power semiconductor 2 is contacted at a distance D from the substrate 4 of at least 70 μm, in particular at least 200 μm.

FIG. 2 shows a schematic sectional representation of a first embodiment of a first template 18. The first template 18 comprises a first cut-out 28, for instance for an emitter contact E, and a second cutout 30, for instance for a gate contact G. The second cut-out 30 is arranged in a corner region of the first cut-out 28, wherein the first template 18 comprises two connecting webs 32 which are arranged orthogonally and which connect the second cut-out 30 with the first cut-out. The first template 18 is embodied in one piece for both cut-outs 28, 30. The further embodiment of the first template 18 in FIG. 2 corresponds to that in FIG. 1.

FIG. 3 shows a schematic sectional representation of a second embodiment of a first template 18, wherein the second cut-out 30, with respect to a longitudinal side of the first cut-out 28, is arranged substantially centrally. The first template 18 comprises three connecting webs 32 which are arranged orthogonally and which connect the second cut-out 30 with the first cut-out 28. The further embodiment of the first template 18 in FIG. 3 corresponds to that in FIG. 2.

FIG. 4 shows a schematic representation of a second embodiment of a method for contacting a power semiconductor 2 on a substrate 4. After applying and drying the second sintered layer 24, a closed third sintered layer 36 is applied to the second sintered layer 24 by means of a third template 34 and after removing the third template 34 is at least partially dried. The third sintered layer 36 is produced from the same material as the first sintered layer 20 and the second sintered layer 24. It is dried analogously to the first sintered layer 20, in the same way as the second sintered layer 24. In a further step, the two contact areas 10, 12 of the power semiconductor 2 which are electrically isolated from one another are contacted on the third sintered layer 36, in particular by means of pressing. The power semiconductor 2 is thereupon connected with a material bond to the substrate 4 by sintering the sintered layers 20, 24, 36. By means of the sintering, a connecting layer 26 is produced, by means of which the power semiconductor 2 is contacted at a distance D from the substrate 4 of at least 70 μm, in particular at least 200 μm. The further method for contacting the power semiconductor 2 in FIG. 4 corresponds to the method in FIG. 1.

FIG. 5 shows a schematic representation of a third embodiment of a method for contacting a power semiconductor 2 on a substrate 4. A closed first sintered layer 20 is applied to the substrate 4 by means of a first template 18 and after removing the first template 18 is at least partially dried. Furthermore, at least one second sintered layer 24 is applied to a transfer unit 38 and at least partially dried. The second sintered layer 24 is applied by means of a mirror-symmetrical template 40 with respect to the first template 18. Alternatively, the second sintered layer 24 is applied with the first template 18 arranged inverted. The transfer unit 38 is Teflon-coated for instance in order to enable a simple transfer of the second sintered layer 24.

The at least partially dried second sintered layer 24 is thereupon transferred by the transfer unit 38 to the first sintered layer 20. The transfer takes place by means of printing and a particularly low increase in temperature, wherein the temperature for transferring the second sintered layer 24 lies dearly below the sintering temperature. Optionally further sintered layers are transferred analogously to the second sintered layer 24 by the transfer unit 38.

In a further step, the two contact areas 10, 12 of the power semiconductor 2 which are electrically isolated from one another are contacted on the second sintered layer 24, in particular by means of pressing. The power semiconductor 2 is thereupon connected with a material bond to the substrate 4 by sintering the sintered layers 20, 24. By means of the sintering, a connecting layer 26 is produced, by means of which the power semiconductor 2 is contacted at a distance D from the substrate 4 of at least 70 μm, in particular at least 200 μm. The further method for contacting the power semiconductor 2 in FIG. 5 corresponds to the method in FIG. 1.

FIG. 6 shows a schematic representation of a fourth embodiment of a method for contacting a power semiconductor 2 on a substrate 4. A closed first sintered layer 20 is applied to the substrate 4 by means of a first template 18 and after removing the first template 18 is at least partially dried. Furthermore, at least one second sintered layer 24 is applied to a metal mold 42 and at least partially dried. The metal mold 42 is separated for instance into two metal plates 42a, 42b which are electrically isolated from one another and which are produced from a material which has good conductivity in electrical and thermal terms such as copper, silver, gold, aluminum, cobalt, platinum and/or their alloys. The metal plates 42a, 42b of the metal mold 42 each have a strength of 10 μm to 200 μm, wherein a first metal plate 42a has a contour which is adjusted to the first contact area 10 of the power semiconductor 2 and wherein a second metal plate 42b has a contour which is adjusted to the second contact area 12 of the power semiconductor 2. The metal mold 42 can also comprise just one metal plate 42a, which is connected to the contact area 10, 12 of the power semiconductor 2, which has the larger surface. For instance, with the IGBT shown in FIG. 6, the one metal plate 42a is connected to the emitter contact E, while the gate contact G is connected to the substrate 4 by means of dispensing or by means of jetting. Alternatively, a metal mold 42 already coated with the second sintered layer 24 is provided.

The metal mold 42 with a side facing away from the at least partially dried second sintered layer is thereupon arranged on the first sintered layer 20, so that the second sintered layer 24 forms the uppermost position. In particular, the metal mold 42 is contacted by pressing on the first sintered layer 20.

In a further step, the two contact areas 10, 12 of the power semiconductor 2 which are electrically isolated from one another are contacted on the second sintered layer 24, in particular by means of pressing. The power semiconductor 2 is then connected with a material bond to the substrate 4 by sintering the sintered layers 20, 24. By means of the sintering, a connecting layer 26 is produced, by means of which the power semiconductor 2 is contacted at a distance D from the substrate 4 of at least 70 μm, in particular at least 200 μm. The connecting layer 26 in FIG. 6 comprises, in addition to the sintered layers 20, 24, the metal mold 42. The further method for contacting the power semiconductor 2 in FIG. 6 corresponds to the method in FIG. 1.

FIG. 7 shows a schematic representation of a power semiconductor module 44, wherein by way of example the power semiconductor 2 has been contacted as described in FIG. 1. Furthermore, the third contact area 14 embodied as a collector contact Cis connected by way of a further connecting layer 46 with a material bond with an in particular multilayer further substrate 48 which has an in particular multilayer, structured metallization 6, in particular copper metallization. The further connecting layer 46 has for instance at least one sintered layer. Furthermore, the power semiconductor module 44 comprises connecting elements 50, 52 for establishing a connection between the metallization 6 of the substrates 4, 48. In particular, the first contact area 10 embodied as an emitter contact E is connected with the first connecting element 50, wherein the second contact area 12 embodied as a gate contact G is connected with the second connecting element 52.

1.-19. (canceled)

20. A method for producing a power semiconductor module, the method comprising:
applying a first sintered layer to a substrate by a first template, the first template having a first thickness;
removing the first template;
at least partially drying the first sintered layer after the first template has been removed;
applying a second sintered layer upon the first sintered layer by a second template, the second template having a second thickness greater than the first thickness;
removing the second template;
at least partially drying the second sintered layer after the second template has been removed;
contacting two contact areas, which are electrically isolated from one another, on a side of a power semiconductor facing the substrate on the second sintered layer, in particular by pressing; and
sintering the first sintered layer and the second sintered layer to produce a structured metal connecting layer and connect the two contact areas of the power semiconductor with a material bond to the substrate.

21. The method of claim 20, wherein the power semiconductor is contacted by the structured connecting layer at a distance from the substrate of at least 70 μm, in particular at least 200 μm.

22. The method of claim 20, further comprising producing the first sintered layer and the second sintered layer from a suspension which contains metal solid state particles and a binding means.

23. The method of claim 20, further comprising arranging the first sintered layer and the second sintered layer one above the other in a direction which is orthogonal to a substrate surface.

24. The method of claim 20, wherein when the second sintered layer is applied, the second template is arranged in such a manner that the second template surrounds the first sintered layer.

25. The method of claim 20, wherein when the first sintered layer is applied and the second sintered layer is applied, the first template and the second template are placed in a planar manner on the substrate in each case.

26. The method of claim 20, wherein the second template is designed to be substantially twice as thick as the first template.

27. The method of claim 20, wherein the first template has a first thickness of 80-100 μm and the second template has a second thickness of 120-200 μm.

28. A method for producing a power semiconductor module, the method comprising:
applying a first sintered layer to a substrate;
at least partially drying the first sintered layer;
applying a second sintered layer to a transfer unit;
at least partially drying the second sintered layer;
transferring the at least partially dried second sintered layer by the transfer unit to the first sintered layer;
contacting two contact areas, which are electrically isolated from one another, on a side of a power semiconductor facing the substrate on the second sintered layer, in particular by pressing; and
sintering the first sintered layer and the second sintered layer to produce a structured metal connecting layer and connect the two contact areas of the power semiconductor with a material bond to the substrate.

29. The method of claim 28, wherein the power semiconductor is contacted by the structured connecting layer at a distance from the substrate of at least 70 μm, in particular at least 200 μm.

30. The method of claim 28, further comprising producing the first sintered layer and the second sintered layer from a suspension which contains metal solid state particles and a binding means.

31. The method of claim 28, further comprising:
applying the first sintered layer to the substrate by a first template; and
applying the second sintered layer to the transfer unit by a second template which is mirror-symmetrical with respect to the first template.

32. A method for producing a power semiconductor module, the method comprising:
applying a first sintered layer to a substrate;
at least partially drying the first sintered layer;
applying a second sintered layer to a metal mold;
at least partially drying the second sintered layer;
positioning the metal mold with a side facing away from the at least partially dried second sintered layer on the first sintered layer;
contacting two contact areas, which are electrically isolated from one another, on a side of a power semiconductor facing the substrate on the second sintered layer, in particular by pressing; and
sintering the first sintered layer and the second sintered layer to produce a structured metal connecting layer and connect the two contact areas of the power semiconductor with a material bond to the substrate.

33. The method of claim 32, wherein the power semiconductor is contacted by the structured connecting layer at a distance from the substrate of at least 70 μm, in particular at least 200 μm.

34. The method of claim 32, further comprising producing the first sintered layer and the second sintered layer from a suspension which contains metal solid state particles and a binding means.

35. The method of claim 32, wherein the metal mold comprises at least two metal plates, and the at least one second sintered layer is applied to the at least two metal plates of the metal mold by a template.

36. A method for producing a power semiconductor module, the method comprising:
applying a first sintered layer to a substrate;
at least partially drying the first sintered layer;
positioning a metal mold, the metal mold coated with a second sintered layer, with a side facing away from the second sintered layer on the first sintered layer;
contacting two contact areas, which are electrically isolated from one another, on a side of a power semiconductor facing the substrate on the second sintered layer, in particular by pressing; and
sintering the first sintered layer and the second sintered layer to produce a structured metal connecting layer and connect the two contact areas of the power semiconductor with a material bond to the substrate.

37. The method of claim 36, wherein the power semiconductor is contacted by the structured connecting layer at a distance from the substrate of at least 70 μm, in particular at least 200 μm.

38. The method of claim 36, further comprising producing the first sintered layer and the second sintered layer from a suspension which contains metal solid state particles and a binding means.

39. A power semiconductor module, comprising:
a substrate;
a power semiconductor having, on a side facing the substrate, at least two contact areas which are electrically isolated from one another, wherein the at least two contact areas of the power semiconductor which are electrically isolated from one another are connected with a material bond to the substrate by a structured metal connecting layer which comprises at least two sintered layers, wherein the at least two sintered layers are applied by way of a template, a second sintered layer of the two sintered layers applied to a metal mold, the metal mold with a side facing away from the second sintered layer positioned on a first sintered layer of the at least two sintered layers, and the at least two contact areas of the power semiconductor which are electrically isolated from one another are contacted on the second sintered layer, in particular by pressing, and thereupon connected with a material bond to the substrate by sintering the at least two sintered layers.

40. The power semiconductor module of claim 39, wherein the power semiconductor is contacted by the structured metal connecting layer at a distance from the substrate of at least 70 μm, in particular at least 100 μm.

41. The power semiconductor module of claim 39, wherein the at least two sintered layers are produced from a suspension which contains metal solid state particles and a binding means.

42. The power semiconductor module of claim 39, wherein the metal mold is arranged between the at least two sintered layers and is connected with a material bond to the at least two sintered layers.

43. The power semiconductor module of claim 39, further comprising:
an in particular multilayer further substrate, with the power semiconductor having on a side facing away from the substrate a third contact area which is connected with a material bond to the further substrate; and
connecting elements respectively connecting the at least two contact areas with a material bond to the further substrate.

44. A converter, comprising a power semiconductor module as set forth in claim 39.
